(19) United States
(12) Patent Application Publication
(10) Pub. No.: US 2026/0214924 A1
(43) Pub. Date: Jul. 23, 2026

(54) SEMICONDUCTOR DEVICE AND METHOD OF FABRICATING THE SAME

(71) Applicant: TAIWAN SEMICONDUCTOR MANUFACTURING COMPANY LTD., HSINCHU (TW)

(72) Inventors: YI-HUAN CHEN, HSINCHU CITY (TW); CHIA-JUI LEE, HSINCHU COUNTY (TW); JHU-MIN SONG, NANTOU COUNTY (TW); FEI-YUN CHEN, HSINCHU (TW)

(21) Appl. No.: 19/034,400

(22) Filed: Jan. 22, 2025

(51) Int. Cl. H10D 30/01; H01L 21/762; H10D 30/65; H10D 64/01; H10D 64/27

(52) U.S. Cl. CPC H10D 30/0285; H10D 30/65; H10D 64/021; H10D 64/518; H10W 10/014; H10W 10/17

(57) ABSTRACT

A semiconductor device and a method of manufacturing the semiconductor device are provided. The method includes steps of forming an isolation feature in a substrate to define a first oxide definition region and a second oxide definition region; forming an insulator layer on the isolation feature and the first oxide definition region; forming a first electrode layer on the insulator layer; patterning the first electrode layer to form a first gate electrode, wherein a corner area of the first oxide definition region is exposed through the first gate electrode; and depositing an inter-layer dielectric (ILD) layer laterally surrounding the first gate electrode and covering the corner area of the first oxide definition region and the isolation feature.

### BACKGROUND

High voltage metal-oxide-semiconductor (MOS) transistors, such as laterally diffused metal oxide semiconductor (LDMOS) transistors, are widely used in applications such as automobiles, display drivers, portable telecommunication devices and medical equipment. The LDMOS transistors are often utilized for high-voltage applications. However, a dielectric breakdown may occur when a gate dielectric is subjected to a voltage high enough to cause the gate dielectric to become electrically conductive, allowing the flow of current.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic top view of a semiconductor device, in accordance with some embodiments of the present disclosure.

FIG. 2 is a schematic cross-sectional view taken along line A-A′ of FIG. 1.

FIG. 3 is a schematic cross-sectional view taken along line B-B′ of FIG. 1.

FIG. 4 is a schematic top view of a gate electrode, in accordance with some embodiments of the present disclosure.

FIG. 5 is a schematic top view of a first oxide definition (OD) region, in accordance with some embodiments of the present disclosure.

FIG. 6 is a schematic top view of a semiconductor device, in accordance with some embodiments of the present disclosure.

FIG. 7 is a schematic cross-sectional view taken along line C-C′ of FIG. 6.

FIG. 8 is a schematic top view of a first OD region, in accordance with some embodiments of the present disclosure.

FIG. 9 is a schematic top view of a gate electrode, in accordance with some embodiments of the present disclosure.

FIG. 10 shows schematic top views of various first OD region of the semiconductor device shown in FIGS. 1 and 7, in accordance with some embodiments of the present disclosure.

FIG. 11 is a schematic top view of a semiconductor device, in accordance with some embodiments of the present disclosure.

FIG. 12 is a schematic cross-sectional view taken along line D-D′ of FIG. 12.

FIG. 13 is a schematic top view of an OD region, in accordance with some embodiments of the present disclosure.

FIG. 14 is a schematic top view of a gate electrode, in accordance with some embodiments of the present disclosure.

FIG. 15 is a schematic top view of an OD region, in accordance with some embodiments of the present disclosure.

FIG. 16 is a schematic top view of a gate electrode, in accordance with some embodiments of the present disclosure.

FIG. 17 is a flowchart of a method of manufacturing a semiconductor device, in accordance with some embodiments of the present disclosure.

FIGS. 18 to 25 are cross-sectional views of intermediate stages of the method of manufacturing a semiconductor photonic device and the interconnect structure, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

The present disclosure is directed to a transistor and a method of method of manufacturing the same. The transistor includes a gate electrode disposed over an oxide definition region and non-overlapped with corner regions of the oxide definition region. This advantageously protects a gate dielectric layer between the oxide definition region and the gate electrode from dielectric breakdown in the vicinity of the corners of the oxide definition region where electrical charge readily accumulates.

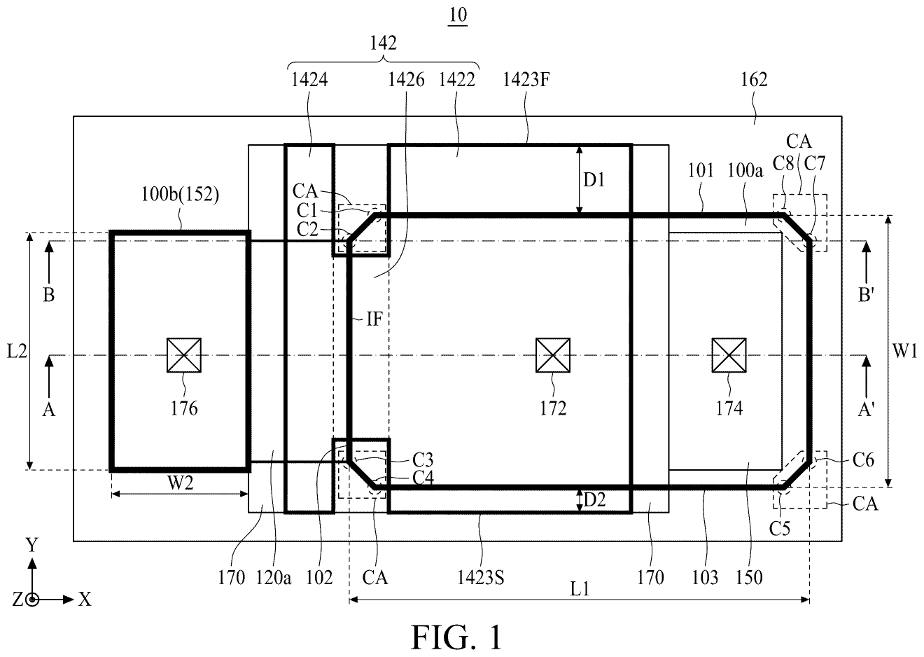

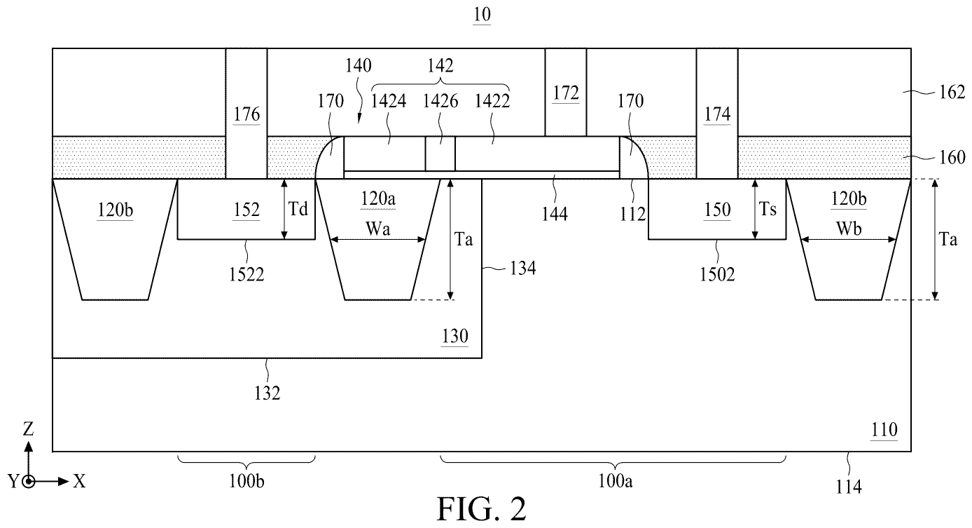

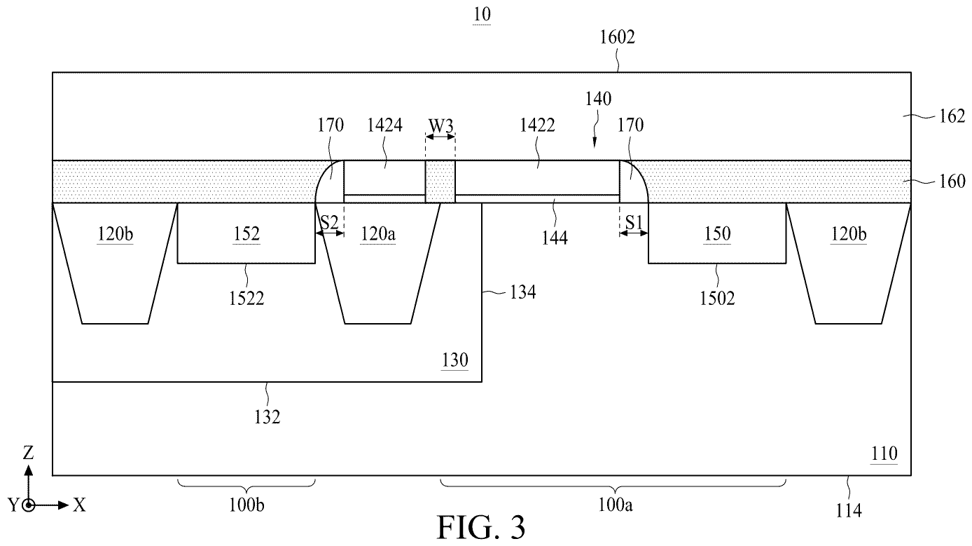

FIG. 1 is a schematic top view of a semiconductor device 10, in accordance with some embodiments of the present disclosure, FIG. 2 is a schematic cross-sectional view taken along line A-A′ of FIG. 1, and FIG. 3 is a schematic cross-sectional view taken along line B-B′ of FIG. 1. Referring to FIGS. 1 to 3, the semiconductor device 10 may be or include a high voltage device, such as a lateral diffusion metal-oxide-semiconductor (LDMOS) transistor. In some embodiments, the semiconductor device 10 includes a substrate 110, a plurality of isolation features 120a and 120b, a well region 130, a gate structure 140, a source region 150, a drain region 152, and one or more inter-level dielectric (ILD) layers, such as a first ILD layer 160 and a second ILD layer 162. The isolation features 120a and 120b, the well region 130, the source region 150, and the drain region 152 are disposed in the substrate 110. The gate structure 140 is disposed on the substrate 110. The first ILD layer 160 is disposed on the substrate 110 and laterally surrounds the gate structure 140. The second ILD layer 162 is disposed on the gate structure 140 and the first ILD layer 160. The semiconductor device 10 may further include spacers 170 on sidewalls of the gate structure 140, wherein the spacer 170 are laterally surrounded by the first ILD layer 160, and a plurality of contacts (e.g., a gate contact 172, a source contact 174, and a drain contact 176) penetrating through the second ILD layer 162.

The substrate 110 has a front surface 112 and a back surface 114 opposite to the front surface 112. The substrate 110 has a first conductivity type. The substrate 110 may be a semiconductor substrate comprising silicon, germanium, gallium arsenide, silicon germanium, silicon carbon, or another semiconductor material used in semiconductor device processing. The substrate 110 may be a bulk substrate or may have a semiconductor-on-insulator structure. In an embodiment, the substrate 110 is doped with a p-type impurity. Alternatively, the substrate 110 may be doped with an n-type impurity.

In some embodiments, the isolation features 120a and 120b are utilized to define a first oxide definition (OD) region 100a and a second OD region 100b. The first and second OD regions 100a and 100b may also be referred to as active regions. The isolation feature 120a and 120b separate the first OD region 100a from the second OD region 100b. The isolation feature 120a may be disposed between the first OD region 100a and the second OD region 100b. The isolation feature 100b may be connected to the isolation feature 100a and surround the first OD region 100a and the second OD region 100b. In some embodiments, the isolation features 120a and 120b collectively define a boundary of the first OD region 100a and the second OD region 100b. In some embodiments, the isolation feature 120a has a width Wa that gradually decreases at positions of increasing distance from the front surface 112 of the substrate 110, as shown in FIG. 2. The isolation feature 120b may have a width Wb that gradually decreases at positions of increasing distance from the front surface 112 of the substrate 110. The width Wa may be same as or different from the width Wb. Further, the isolation feature 120a may have a thickness Ta substantially equal to a thickness Tb of the isolation feature 120b. The present disclosure, however, is not limited thereto. The isolation features 120a and 120b may have one or more uniform widths. The isolation feature 120a and 120b may be shallow trench isolation (STI) structures.

In some embodiments, the first OD region 100a and the second OD region 100b have different shapes from a top-view perspective. The first OD region 100a and the second OD region 100b may have a polygon shape containing at least four sides. For example, as shown in FIG. 1, the first OD region 100a may have an octagonal shape, and the second OD region 100b may have a rectangular shape with right-angle corners. The first OD region 100a has a length L1 in the X-direction and a width W1 in the Y-direction. The second OD region 100b has a length L2 in the Y-direction and a width W2 in the X-direction. The width W1 of the first OD region 100a may be greater than the length L2 of the second OD region 100b. The length L1 of the first OD region 100a may be greater than the width W2 of the second OD region 100b.

As shown in FIG. 2, the well region 130 extends in the substrate 110 from the front surface 112 of the substrate 110. In some embodiments, the well region 130 has a bottom surface 132 between the front surface 112 and the back surface 114 of the substrate 110. The well region 120 may have a second conductivity type opposite to the first conductivity type of the substrate 110. A p-n junction may be formed between an interface between the substrate 110 and the well region 130. In some embodiments, the isolation feature 120a is disposed in the well region 130. The well region 130 may have an impurity concentration greater than an impurity concentration of the substrate 110.

The gate structure 140 is disposed on the substrate 110 and the isolation features 120a and 120b. The gate structure 140 includes a gate electrode 142 and a gate dielectric layer 144. The gate dielectric layer 144 may electrically isolate the gate electrode 142 from the substrate 110. The gate dielectric layer 144 separates the gate electrode 142 from the substrate 110 and the isolation feature 120a. In some embodiments, the gate dielectric layer 144 has a substantially uniform thickness. The gate dielectric layer 144 may include an oxide (e.g., silicon dioxide (SiO₂), aluminum oxide (Al₂O₃), or hafnium oxide (HfO₂)), a high-dielectric-constant (high-k) dielectric material, other dielectric materials, or a combination thereof. In some embodiments, the gate dielectric layer 144 may include one or more layers, wherein each layer is made using one or more of the dielectric materials mentioned above.

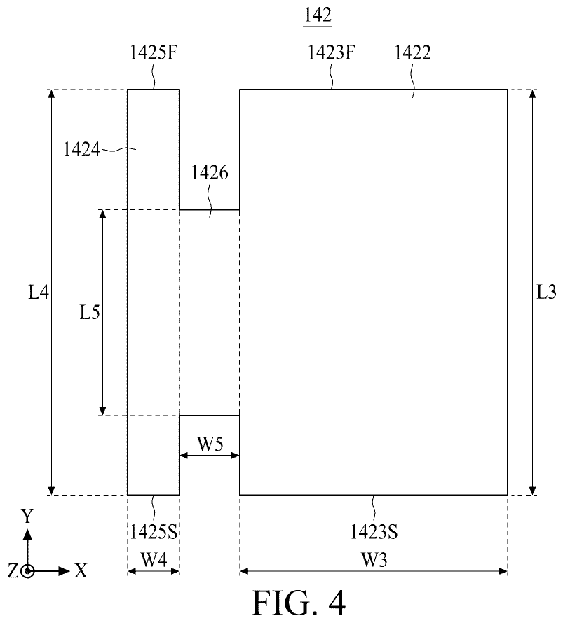

FIG. 4 is a schematic top view of the gate electrode 142, in accordance with some embodiments of the present disclosure. Referring to FIG. 4, the gate electrode 142 may have an H-shape in a top-view perspective. The H-shaped is, for example, an asymmetry H-shape. In some embodiments, the gate electrode 142 includes semiconductor material, such as polysilicon. In alternative embodiments, the gate electrode 142 includes a metallic material or a metal compound. The metallic material may include, for example but not limited thereto, copper (Cu), aluminum (Al), tungsten (W), silver (Ag), gold (Au), nickel (Ni), another suitable material, alloys thereof, or a combination thereof. The metal compound may include, for example but not limited thereto, titanium nitride (TiN), tantalum nitride (TaN), metal silicide, other suitable materials, or a combination thereof. Other materials suitable for forming the gate electrode 210 are within the scope of the present disclosure.

The gate electrode 142 may include a first primary section 1422, a second primary section 1424, and a connecting section 1426. The first and second primary sections 1422 and 1424 are disposed on opposite sides of the connecting section 1426. The connecting section 1426 connects the first primary section 1422 to the second primary section 1424. The first primary section 1422, the second primary section 1424, and connecting segment 1426 may include a strip and rectangular shape.

The first primary section 1422 has a length L3 in the Y-direction and a width W3 in the X-direction. The second primary section 1424 has a length L4 in the Y-direction and a width W4 in the X-direction. In some embodiments, the length L3 of the first primary section 1422 is substantially equal to the length L4 of the second primary section 1424. In some embodiments, the width W3 of the first primary section 1422 is less than the width W4 of the second primary section 1424. In the top view perspective, the first primary section 1422 has a first sidewall 1423F and a second sidewall 1423S, and the second primary section 1424 has a first sidewall 1425F and a second sidewall 1425S. The first sidewalls 1423F and 1425F are spaced from and aligned with each other in the X-direction, and the second sidewalls 1423S and 1425S are spaced from and aligned with each other in the X-direction.

The connecting section 1426 has a length L5 in the Y-direction and a width W5 in the X-direction. The first primary section 1422 is spaced from the second primary section 1424 by the width W5. The length L5 of the connecting section 1426 is less than the length L3 of the first primary section 1422. The width W5 of the connecting section 1426 may be less than the width W3 of the first primary section 1422.

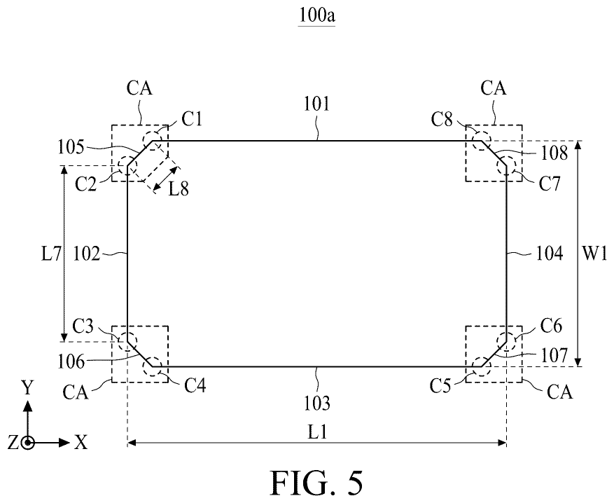

FIG. 5 is a schematic top view of the first OD region 100a, in accordance with some embodiments of the present disclosure. Referring to FIG. 5, the first OD region 100a may have an octagonal shape from a top-view perspective. The octagonal first OD region 100a includes eight sidewalls 101 to 108. In some embodiments, the sidewalls 101 to 108 define a boundary of the first oxide definition region 100a. Each of the sidewalls 101 to 108 may be substantially planar. In some embodiments, the sidewall 101 is parallel to the sidewall 103, and the sidewall 102 is parallel to the sidewall 104. The sidewall 101 may be orthogonal to the sidewall 102. The length L1 of the first OD region 100a is, for example, a distance between the sidewalls 102 and 104, and the width W1 of the first OD region 100a is, for example, a distance between the sidewalls 101 and 103. The sidewalls 101 and 103 have a length L6 in the X-direction, which may be less than the length L1 of the first OD region 100a. The sidewalls 102 and 104 have a length L7, which may be less than the width W1 of the first OD region 100a.

The sidewalls 105 to 108 are inclined sidewalls. In some embodiments, the sidewall 105 is arranged between the orthogonal sidewalls 101 and 102. The sidewall 105 may connect the sidewall 101 to the sidewall 102 to form corners C1 and C2, and the sidewall 106 may connect the sidewall 102 to the sidewall 103 to form corners C3 and C4. In some embodiments, the sidewall 107 is parallel to the sidewall 105 and connected to the sidewalls 103 and 104 to form corners C5 and C6. Further, the sidewall 108 is parallel to the sidewall 106 and connected to the sidewalls 101 and 104 to form corners C7 and C8. In some embodiments, the sidewalls 105 to 108 have identical lengths. For example, the sidewalls 105 to 108 have a length L8, which is not only less than the length L6 but also less than the length L7. In some embodiments, the corner C1 to C8 are obtuse angles. In some embodiments, the corner C1 to C8 have identical angles (e.g., about 135 degrees).

The first OD region 100a may include four corner areas CA. Each corner area CA is defined as an area connecting two or more sidewalls and including at least one corner of the first OD region 100a. For example, each of the corner areas CA of the first OD region 100a contains three connected sidewalls, such as the sidewalls 101, 102, and 105, and two corners, such as the corners C1 and C2.

In some embodiments, the first OD region 100a includes the corners C1 to C8, wherein none of the corners C1 to C8 includes a sharp corner with an angle equal to or less than 90 degrees. In a comparative embodiment where the rectangular first OD region includes sharp corners and the gate electrode vertically overlaps the sharp corners, electrical charge may easily accumulate at the sharp corners and form potential differences with the gate electrode, resulting in a risk of dielectric breakdown of the gate dielectric layer. To eliminate or reduce the risk of dielectric breakdown of the gate dielectric layer 144, the first OD region 100a of the present disclosure is provided without any sharp corners. As a result, accumulation of electrical charge may be almost completely suppressed, and the gate dielectric 144 may have improved endurance. A reliability of the semiconductor device 10 is thereby improved.

Referring to FIGS. 1, 4, and 5, in some embodiments, the gate electrode 142 is disposed over the first OD region 100a and the isolation feature 120a and 120b. The first primary section 1422 of the gate electrode 142 vertical overlaps the first OD region 100a and the isolation feature 120b. The first primary section 1422 further overlaps the sidewalls 101 and 103 of the first OD region 100 from a top-view perspective. The second primary section 1424 of the gate electrode 142 may vertical overlap the isolation features 120a and 120b. The connecting section 1426 of the gate electrode 142 may vertically overlap the isolation feature 120a and the first OD region 100a. In addition, the connecting section 1426 vertically overlaps an interface IF between the first OD region 100a and the isolation feature 120a. The connecting section 1426 may overlap the sidewall 102 of the first OD region 100a from a top-view perspective. In some embodiments, the first primary section 1422 is non-overlapped with the isolation feature 120a, and the second primary section 1424 is non-overlapped with the first OD region 100a. In some embodiments, the connecting section 1426 is non-overlapped with the isolation feature 120b.

In some embodiments, the corners C1 to C4 of the first OD region 100a are close to the isolation feature 120a, and the corners C5 to C8 of the first OD region 100a are distal from the isolation feature 120a. For example, the corners C1 to C4 of the first OD region 100a are positioned between the first and second primary sections 1422 and 1424 of the gate electrode 142. The connecting section 1426 of the gate electrode 142 may have the length L5 less than the length L7 of the sidewall 102 of the first OD region 100a, and the first primary section 1422 may have the width W3 less than the length L1 of the first OD region 100a, which allows the sidewalls 105 to 108 and the corners C1 to C8 and to be exposed through the gate electrode 142 from a top-view perspective. In other words, the gate electrode 142 is non-overlapped with the sidewalls 105 to 108 and the corners C1 to C8 of the first OD region 100a in a top-view perspective. This arrangement of the corners C1 to C8 advantageously prevents the gate dielectric layer 144 from dielectric breakdown in the vicinity of the corners C1 to C8 of first OD region 100a where electrical charge tend to accumulate. Therefore, this arrangement of the corners C1 to C8 advantageously reduces voltage-induced stress on the gate dielectric layer 144, which may otherwise adversely cause the dielectric breakdown of the gate dielectric layer 144 in the vicinity of the corners C1 to C8 of first OD region 100a. The semiconductor device 10 can be formed with a higher reliability while protecting the gate dielectric layer 144 from dielectric breakdown.

The sidewall 101 of the first OD region 100a is spaced apart from the first sidewall 1423F of the first primary section 1422 by a distance D1 in the Y-direction. The sidewall 103 of the first OD region 100a is spaced apart from the second sidewall 1423S of the first primary section 1422 by a distance D2 in the Y-direction. The distance D1 may be different from the distance D2. For example, the distance D1 may be greater than the distance D2. The present disclosure, however, is not limited thereto. The distance D1 may be equal to or less than the distance D2.

Referring again to FIGS. 1 to 3, the gate dielectric layer 144 may have a pattern same as a pattern of the gate electrode 142. In other words, the gate dielectric layer 144 may have an asymmetrical H-shape in a top-view perspective. In some embodiments, the source region 150 and the drain region 162 are disposed on two sides of the gate structure 140. The source region 150 and the drain region 152 are exposed through the gate structure 140. The source region 150 may be disposed in a part of the first OD region 100a. The source region 150 is spaced apart from the first primary section 1422 of the gate electrode 144 by a distance S1 in the X-direction (as shown in FIG. 3). The source region 150 may have a bottom surface 1502 between the front surface 112 of the substrate 110 and the bottom surface 132 of the well region 130. The source region 150 has a thickness Ts in the Z-direction, which is less than the thicknesses Ta and Tb of the isolation features 120a and 120b.

In some embodiments, the drain region 152 is formed in at least a part of the second OD region 100a. As shown in FIG. 3, the drain region 152 is spaced apart from the second primary section 1424 of the gate electrode 142 by a distance S2 in the X-direction. The distance S2 may be equal the distance S1. The drain region 152 has a thickness Td in the Z-direction, which is less than the thicknesses Ta and Tb of the isolation features 120a and 120b. The drain region 152 in the well region 130 may have a bottom surface 1522 between the front surface 112 of the substrate 110 and the bottom surface 132 of the well region 130. The bottom surface 1502 of the source region 150 may be flushed with the bottom surface 1522 of the drain region 152. The source region 150 and the drain region 152 may be formed from the front surface 112 of the substrate 110 by doping the substrate 110 with one or more implantation operations. The source region 150 and the drain region 152 may have upper surfaces coplanar with the front surface 112 of the substrate 110. The source region 150 and the drain region 160 may have an impurity concentration greater than an impurity concentration of the well region 130.

Referring to FIGS. 2 and 3, one of the spacers 170 is disposed on the sidewall of the first primary section 1422 proximal to the source region 150, and the other spacer 170 is disposed on the sidewall of the second primary section 1424 proximal to the drain region 152. In some embodiments, the first ILD layer 160 covers the isolation features 120a and 120b, the well region 130, the source region 150, and the drain region 152 in the substrate 110 and laterally surrounds the spacers 170 on sidewalls of the gate structure 140. The first ILD layer 160 may be in contact with corners areas CA of the first OD region 100a.

The second ILD layer 162 is disposed on the gate electrode 142 and the first ILD layer 160. The gate contact 172 in the second ILD layer 162 is connected to the gate electrode 142. The source contact 174 and the drain contact 176 penetrates both the second ILD layer 162 and the first ILD layer 160. The source contact 174 and the drain contact 176 are laterally surrounded by the first and second ILD layers 160 and 162, and are respectively connected to the source region 150 and the drain region 152. The gate contact 172, the source contact 174, and the drain contact 176 may include metallic material such as copper, aluminum, tungsten, titanium (Ti), tantalum (Ta), cobalt (Co), ruthenium (Ru), molybdenum (Mo), alloys thereof, or combinations thereof. Other suitable materials within the contemplated scope of the disclosure may also be used. The first and second ILD layers 160 and 162 may include oxide (such as silicon oxide), nitride (such as silicon nitride), oxynitride (such as silicon oxynitride), carbide (such as silicon carbide), oxycarbide (such as silicon oxycarbide), low-dielectric-constant (low-k) dielectric materials, ultra-low-k dielectric materials, other dielectric materials, or a combination thereof.

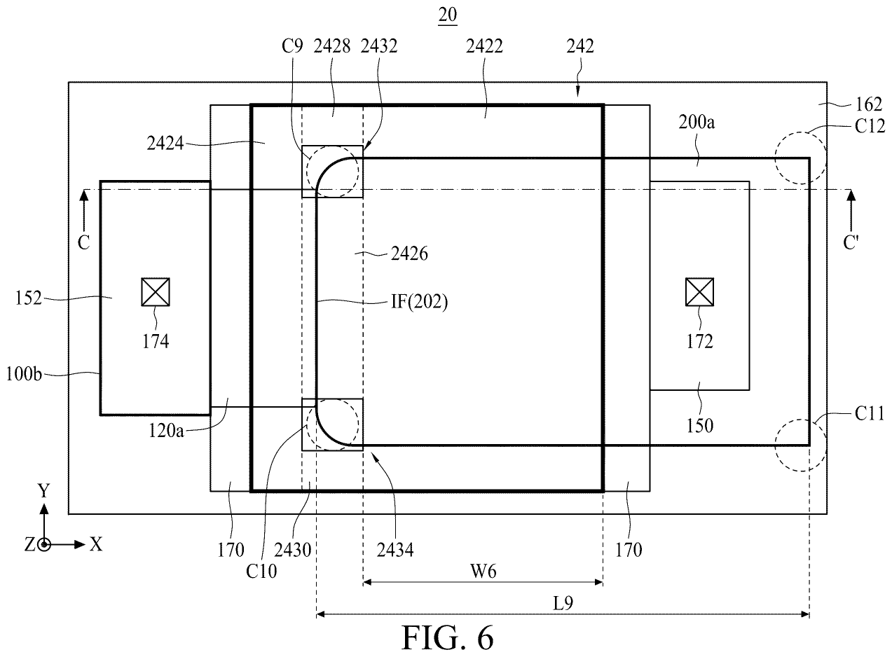

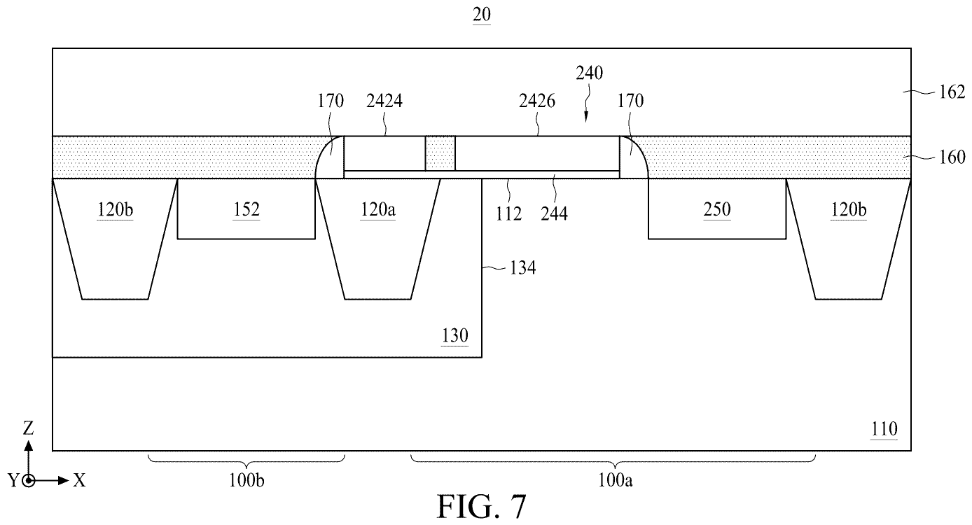

FIG. 6 is a schematic top view of a semiconductor device 20, in accordance with some embodiments of the present disclosure, and FIG. 7 is a schematic cross-sectional view taken along line C-C′ of FIG. 6. The semiconductor device 20 is similar to the semiconductor device 10 discussed above, except that the first OD region 100a and the gate structure 140 of the semiconductor device 10 are replaced in the semiconductor device 20 by a first OD region 200a and a gate structure 240, respectively. Referring to FIGS. 6 and 7, the first OD region 200a may be defined by the isolation features 120a and 120b. The gate structure 240 includes a gate electrode 242 and a gate dielectric layer 244 include different shapes, as discussed below in more detail.

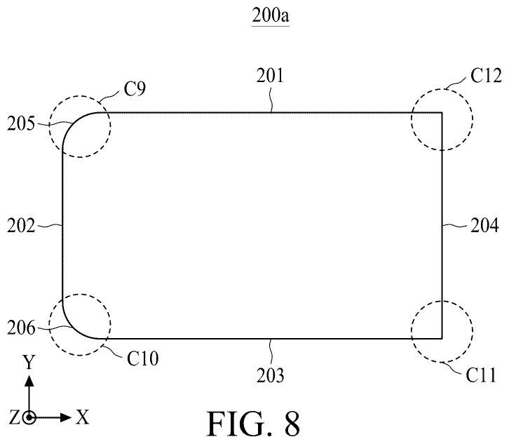

FIG. 8 is a schematic top view of the first OD region 200a, in accordance with some embodiments of the present disclosure. Referring to FIG. 8, in some embodiments, the first OD region 200a includes four substantially planar sidewalls 201 to 204 and two curved sidewalls 205 and 206. In some embodiments, the sidewalls 201 to 106 define a boundary of the first oxide definition region 200a. The sidewall 201 may be parallel to the sidewall 203, and the sidewall 202 may be parallel to the sidewall 204. The sidewall 205 may connect the sidewall 201 to the sidewall 202 to thereby form a rounded corner C9. The sidewall 206 may connect the sidewall 202 to the sidewall 203 to thereby form a rounded corner C10. The sidewall 203 is directly connected to the sidewall 204 and a sharp corner C11 is included between the sidewalls 203 and 204. The sidewall 201 is directly connected to the sidewall 204 and a sharp corner C12 is included between the sidewalls 201 and 204.

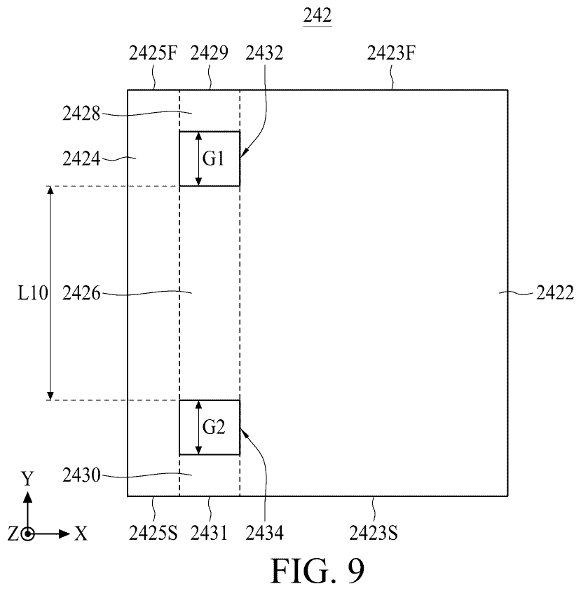

FIG. 9 is a schematic top view of the gate electrode 242, in accordance with some embodiments of the present disclosure. Referring to FIG. 9, the gate electrode 242 may include a first primary section 2422, a second primary section 2424, a first connecting section 2426, a second connecting section 2428, and a third connecting section 2430. In some embodiments, the first connecting section 2426, the second connecting section 2428, and the third connecting section 2430 are separated from and aligned with each other in the Y-direction, with the first connecting section 2426 between the second and third connecting sections 2428 and 2430. The first connecting section 2426 may be spaced apart from the second connecting section 2428 by a distance G1 and spaced apart from the third connecting section 2430 by a distance G2. The distance G1 may be equal to the distance G2. The first connecting section 2422 has a length L10 in the Y-direction, which may be greater than the distance G1/G2.

Each of the first connecting section 2426, the second connecting section 2428, and the third connecting section 2430 may connect the first primary section 2422 to the second primary section 2424. In some embodiments, the first primary section 2422, the second primary section 2424, the first connecting section 2426, and the second connecting section 2428 collectively define a trench 2432 that penetrates through the gate electrode 242. In addition, the first primary section 2422, the second primary section 2424, the first connecting section 2426, and the second connecting section 2430 collectively define a trench 2434 that penetrates through the gate electrode 242. Each of the trenches 2432 and 2434 may have a rectangular or square shape in a top-view perspective.

The first primary section 2422 has a first side 2423F and a second side 2423S, and the second primary section 2424 has a first side 2425F and a second side 2425S. The second connecting section 2428 may have a first side 2429 that is flush with the first side 2423F of the first primary section 2422 and with the first side 2425F of the second primary section 2424. The third connecting section 2430 may have a side 2431 that is flush with the second side 2423S of the first primary section 2422 and with the second side 2425S of the second primary section 2424.

Referring to FIGS. 6 to 9, in some embodiments, the gate electrode 242 is disposed over the first OD region 100a and the isolation features 120a and 120b, the rounded corners C9 and C10 are close to the isolation feature 120a, and the sharp corners C11 and C12 are distal from the isolation feature 120a. The gate electrode 242 is positioned to allow the trenches 2432 and 2434 to be vertically aligned with the rounded corners C9 and C10, respectively, in order to prevent electrical charge from accumulating and forming potential differences that may lead to dielectric breakdown of a gate dielectric layer 244 of the gate structure 240.

In some embodiments, the first primary section 2422 of the gate electrode 242 vertically overlaps the first OD region 200a and the isolation feature 120b, and the second primary section 2424 of the gate electrode 242 vertically overlaps the second OD region 100b. The first connecting section 2426 of the gate electrode 242 may vertically overlaps the first OD region 200a and the isolation feature 120a. In addition, the first connecting section 2422 overlaps an interface IF between of the first OD region 200a and the isolation feature 120a from a top-view perspective. The first connecting section 2426 may overlap the sidewall 202 from a top-view perspective. The second and third connecting sections 2428 and 2430 may vertical overlap the isolation feature 120b. In some embodiments, the first primary section 2422 is non-overlapped with the isolation feature 120a, and the first connecting section 1426 is non-overlapped with the isolation feature 120b. In some embodiments, the second primary section 2424 and the second and third connecting section 2428 and 2430 are non-overlapped with the first OD region 200a.

Referring to FIG. 7, in some embodiments, the gate dielectric layer 244 may electrically isolate the gate electrode 242 from the substrate 110. The gate dielectric layer 244 is disposed between the gate electrode 240 and the substrate 110, between the gate electrode 240 and the isolation feature 120a, and between the gate electrode 240 and the well region 130. In some embodiments, gate electrode 242 and a gate dielectric layer 244 include different shapes. At least a portion of the gate dielectric layer 244 are thus exposed through the gate electrode 244 and in contact with the first ILD layer 162. For example, the trenches 2432 and 2434 of the gate electrode 242 expose portions of the gate dielectric layer 244. The gate dielectric layer 244 may be further disposed between the first ILD layer 160 and the isolation feature 120a and between the first ILD layer 160 and the well region 130.

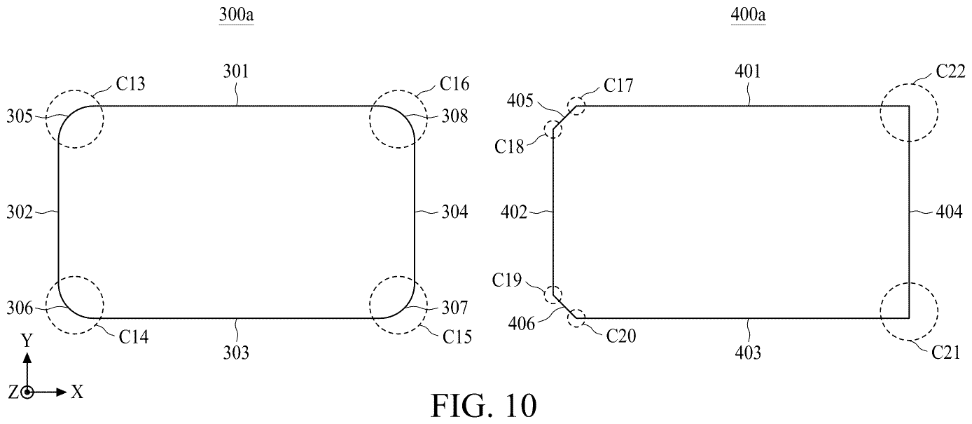

FIG. 10 shows schematic top views of first OD regions 300a and 400a of the semiconductor devices 10 and 20, respectively, in accordance with some embodiments of the present disclosure. Referring to a left subfigure of FIG. 10, the first OD region 300a includes a rectangular shape with rounded corners C13 to C16. The first OD region 300a includes four substantially planar sidewalls 301 to 304 and four curved sidewalls 305 to 308. In some embodiments, the sidewalls 301 to 308 define a boundary of the first oxide definition region 300a. The sidewall 301 is parallel to the sidewall 303, and the sidewall 302 is parallel to the sidewall 304. The curved sidewall 305 may connect the sidewall 301 to the sidewall 302, the curved sidewall 306 may connect the sidewall 302 to the sidewall 303, the curved sidewall 307 may connect the sidewall 303 to the sidewall 304, and the curved sidewall 308 may connect the sidewall 301 to the sidewall 304. The rounded corners C13 to C16 may be used to eliminate or reduce the risk of dielectric breakdown of the gate dielectric layer 144/244.

Referring to a right subfigure of FIG. 10, the first OD region 400a includes six sidewalls 401 to 406. The first OD region 400a may have a substantially hexagonal shape. The sidewalls 401 to 406 may be substantially planar sidewalls. In some embodiments, the sidewalls 401 to 406 define a boundary of the oxide definition region 400a. In some embodiments, the sidewall 401 is parallel to the sidewall 403, and the sidewall 402 is parallel to the sidewall 404. The sidewall 405 may connect the sidewall 401 to the sidewall 402, thereby forming a corner C17 between the sidewalls 401 and 405 and a corner C18 between the sidewalls 402 and 405. The sidewall 406 may connect the sidewall 402 to the sidewall 403, thereby forming a corner C19 between the sidewalls 402 and 406 and a corner C20 between the sidewalls 403 and 406. The corners C17 to C20 may have identical angles (e.g., about 135 degrees). The sidewall 404 may connect the sidewall 401 to the sidewall 403, thereby forming a sharp corner C21 between the sidewalls 403 and 404 and forming another sharp corner C22 between the sidewalls 401 and 404. The sharp corners C21 and C22 may each be a right angle of about 90 degrees. The corners C17 to C20 may be used to eliminate or reduce the risk of dielectric breakdown of the gate dielectric layer 144/244.

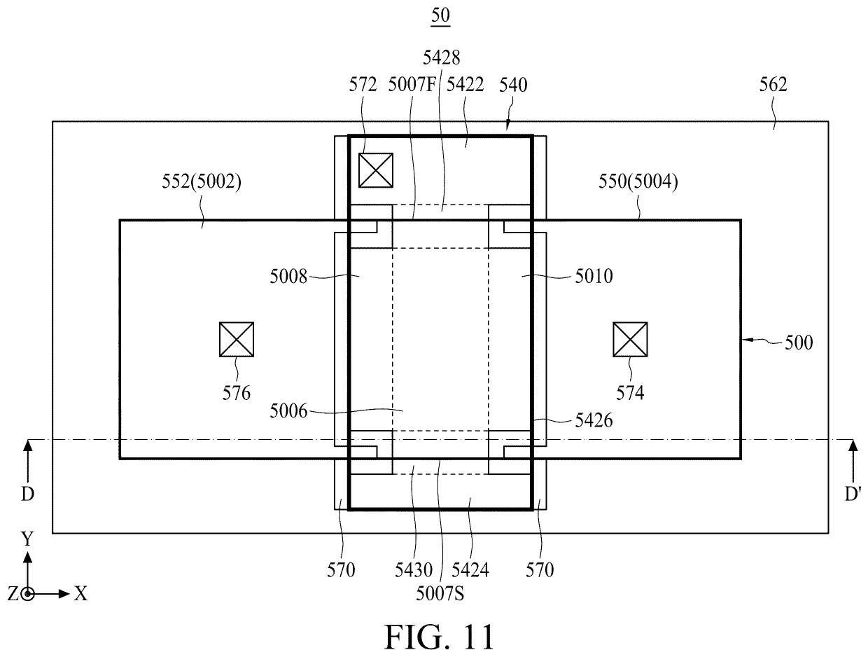

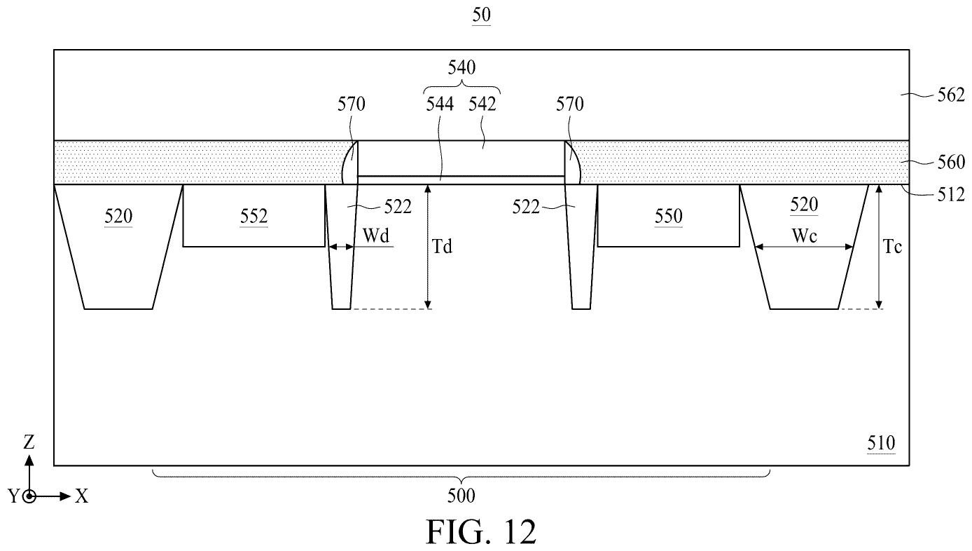

FIG. 11 is a schematic top view of a semiconductor device 50, in accordance with some embodiments of the present disclosure, and FIG. 12 is a schematic cross-sectional view taken along line D-D′ of FIG. 11. Referring to FIGS. 11 and 12, the semiconductor device 50 may include a substrate 510, isolation features 520 and 522, a gate structure 540, a source region 550, a drain region 552, a first ILD layer 560, a second ILD layer 562, spacers 570, a gate contact 572, a source contact 574, and a drain contact 576. In some embodiments, the isolation features 520 and 522 are disposed in the substrate 510 to define an oxidation (OD) region 500 extending in the X-direction. The isolation feature 520 may have a ring shape (e.g., a rectangular ring shape), and the isolation features 522 may have a rectangular shape or a square shape from a top-view perspective. The isolation features 522 are connected to the isolation feature 520. The isolation features 520 and 522 define a boundary of the oxide definition region 500. The isolation features 522 may have a depth Td equal to a depth Tc of the isolation feature 520. The isolation features 522 has a width Wd, which is less than a width Wc of the isolation feature 520. The isolation features 520 may be formed simultaneously with the isolation feature 522.

The gate structure 540 is disposed on the OD region 500 and the isolation feature 520. The gate structure 540 may include a gate electrode 542 and a gate dielectric layer 544. The gate dielectric layer 544 may electrically isolate the gate electrode 542 from the substrate 510. In some embodiments, the spacers 570 are disposed on opposite sidewalls of the gate structure 540. The source region 550 and the drain region 552 are disposed in the OD region 500 and at two sides of the gate structure 540. The first ILD layer 560 laterally surround the gate structure 540 and the spacers 570. The second ILD layer 562 is disposed on the gate electrode 542 and the first ILD layer 560. In some embodiments, the gate contact 572 is connected to the gate electrode 542 and laterally surrounded by the second ILD layer 562. The source contact 574 and the drain contact 576 are connected to the source region 550 and the drain region 552, respectively. The source contact 574 and the drain contact 576 may be laterally surrounded by the first and second ILD layers 560 and 562.

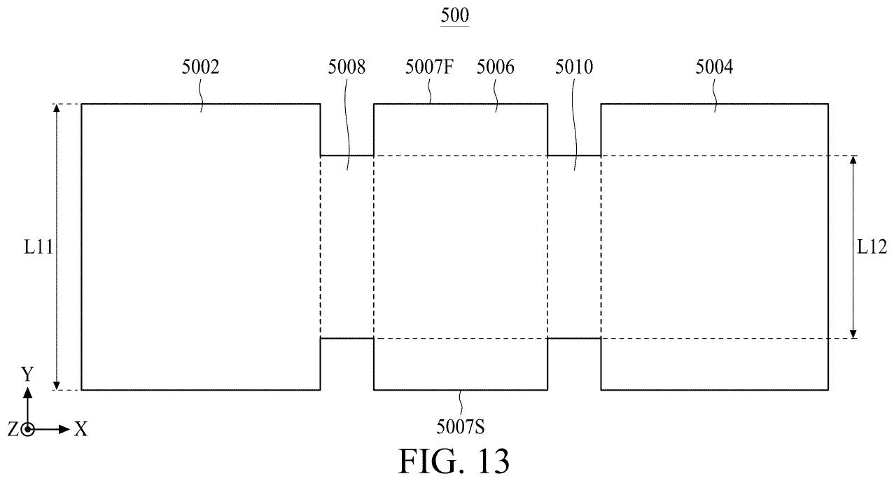

FIG. 13 is a schematic top view of the OD region 500, in accordance with some embodiments of the present disclosure. Referring to FIG. 13, the OD region 500 may include a first end section 5002, a second end section 5004, a middle section 5006, a first connecting section 5008, and a second connecting section 5010. In some embodiments, the first end section 5002, the second end section 5004, and the middle section 5006 are separated from and aligned with each other in the X-direction. The middle section 5006 is disposed between the first and second end sections 5002 and 5004. The first connecting section 5008 may connect the first end section 5002 to the middle section 5006, and the second connecting section 5010 may connect the middle section 5006 to the second end section 5004. The first end section 5002, the second end section 5004, and the middle section 5006 have a length L11 in the Y-direction, the first and second connecting sections 5008 and 5010 have a length L12 in the Y-direction, and the length L12 is less than the length L11. The middle section 5006 has a first sidewall 5007F and a second sidewall 5007S opposite to the first sidewall 5007F.

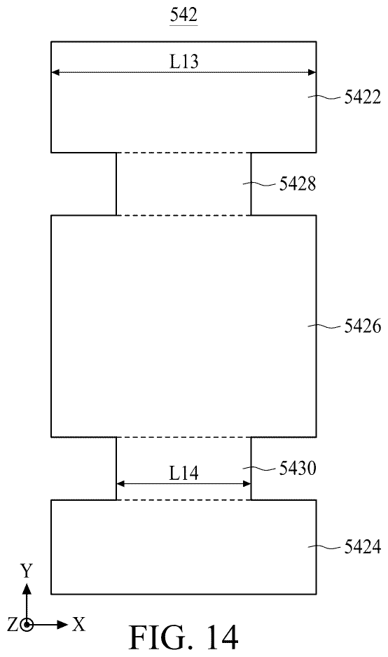

FIG. 14 is a schematic top view of the gate electrode 542, in accordance with some embodiments of the present disclosure. Referring to FIG. 14, the gate electrode 542 may include a first primary section 5422, a second primary section 5424, a third primary section 5426, a first connecting section 5428, and a second connecting section 5430. In some embodiments, the first to third primary sections 5422 to 5426 are separated from and aligned with each other in the Y-direction. The third primary section 5426 is disposed between the first and second primary sections 5422 and 5424. The first connecting section 5428 may connect the first primary section 5422 to the third primary section 5426, and the second connecting section 5430 may connect the second primary section 5424 to the third primary section 5426. The first to third primary sections 5422 to 5426 have a length L13 in the X-direction, the first and second connecting sections 5428 and 5430 have a length L14 in the X-direction, and the length L14 is less than the length L13.

Referring to FIGS. 11, 13, and 14, in some embodiments, the first and second primary sections 5422 and 5424 of the gate electrode 542 may vertically overlap the isolation feature 520. The third primary section 5426 of the gate electrode 542 may vertically overlaps the middle section 5006, the first connecting section 5008, and the second connecting section 5010 of the OD region 500. The first 5002 section 5428 of the gate electrode 542 may vertically overlap the middle section 5006 of the OD region 500 and the isolation feature 520. The first connecting section 5428 of the gate electrode 542 covers the first sidewall 5007F of the middle section 5006 of the OD region 500. The second connecting section 5430 of the gate electrode 542 may vertically overlap the middle section 5006 of the OD region 500 and the isolation feature 520. The second connecting section 5428 of the gate electrode 542 covers the second sidewall 5007S of the middle section 5006 of the OD region 500. In some embodiments, the spacers 570 is connected to the isolation feature 522. The first ILD layer 562 may be connected to the isolation feature 522.

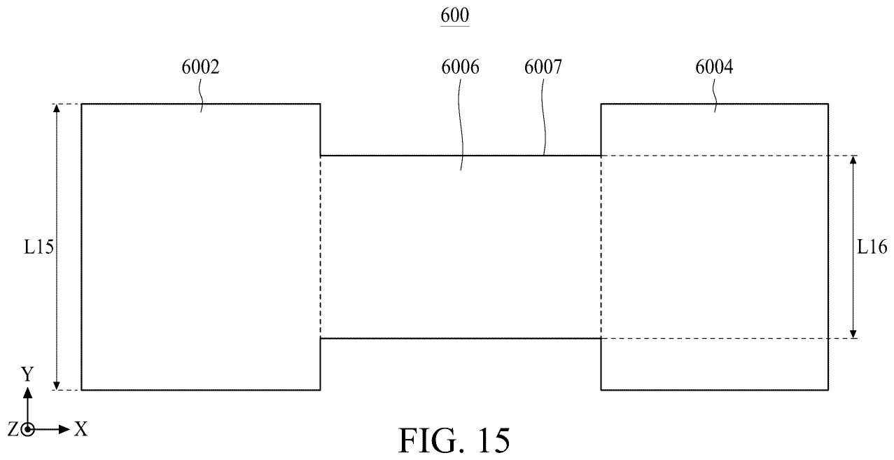

In many instances, the OD region 500 shown in FIG. 13 may be replaced by another structure that shows in FIG. 15. Referring to FIG. 15, an OD region 600 may include a first end section 6002, a second end section 6004, and a middle section 6006. In some embodiments, the middle section 6006 is disposed between the first end section 6002 and the second end section 6004. The middle section 6006 may connect the first end section 6002 to the second end section 6004. The first and second end section 6002 and 6004 have a length L15 in the Y-direction, the third primary section 6006 has a length L16 in the Y-direction, and the length L15 is greater than the length L16. The OD region 600 may have an H-shape in a top-view perspective. When the gate electrode 542 is disposed over the OD region 600, the third primary section 5426 of the gate electrode 542 may vertically overlap the middle section 6006 of the OD region 600. In some embodiments, the first connecting sections 5428 overlaps a first sidewall 6007F in the OD region 600, and the second connecting section 5430 overlaps a second sidewall 6007S of the OD region 600 from a top-view perspective.

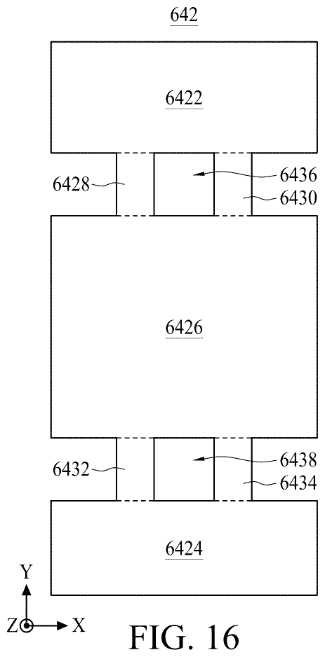

In some embodiments, the gate electrode 542 shown in FIG. 14 may be replaced by another structure shown in FIG. 16. Referring to FIG. 16, a gate electrode 642 may include a first primary section 6422, a second primary section 6424, a third primary section 6426, and a plurality of connecting sections, such as first to fourth connecting sections 6428 to 6434. In some embodiments, the first to third primary sections 6422 to 6426 are separated from each other and aligned with each other in the Y-direction. The third primary section 6426 is disposed between the first and second primary sections 6422 and 6424. In some embodiments, the first and second connecting sections 6428 and 6430 are disposed between the first and third primary sections 6422 and 6426. The first and second connecting sections 6428 and 6430 may be separated from each other and aligned with each other in the X-direction. The first and second connecting sections 6428 and 6430 connect the first primary section 6422 to the third primary section 6426 and form a trench 6436 penetrating through the gate electrode 642.

In some embodiments, the third and fourth connecting sections 6432 and 6434 are disposed between the second primary section 6424 and the third primary section 6426. The third and fourth connecting sections 6432 and 6434 may be separated from each other and aligned with each other in the X-direction. The third and fourth connecting sections 6432 and 6434 connect the second primary section 6424 to the third primary section 6426 and form a trench 6438 penetrating through the gate electrode 642. In some embodiments, the first and third connecting sections 6428 and 6332 are aligned with each other in the Y-direction, and the second and fourth connecting sections 6430 and 6334 are aligned with each other in the Y-direction. The gate electrode 642 may be disposed over the OD region 500 shown in FIG. 13, and the third primary section 6426 may vertically overlap the middle section 5006 of the OD region 500. In some embodiments, the first and second connecting sections 6428 and 6430 overlap the first sidewall 5007F of the OD region 500 from a top-view perspective. In some embodiments, the third and fourth connecting sections 6432 and 6434 overlap the second sidewall 5007S of the OD region 500 from a top-view perspective.

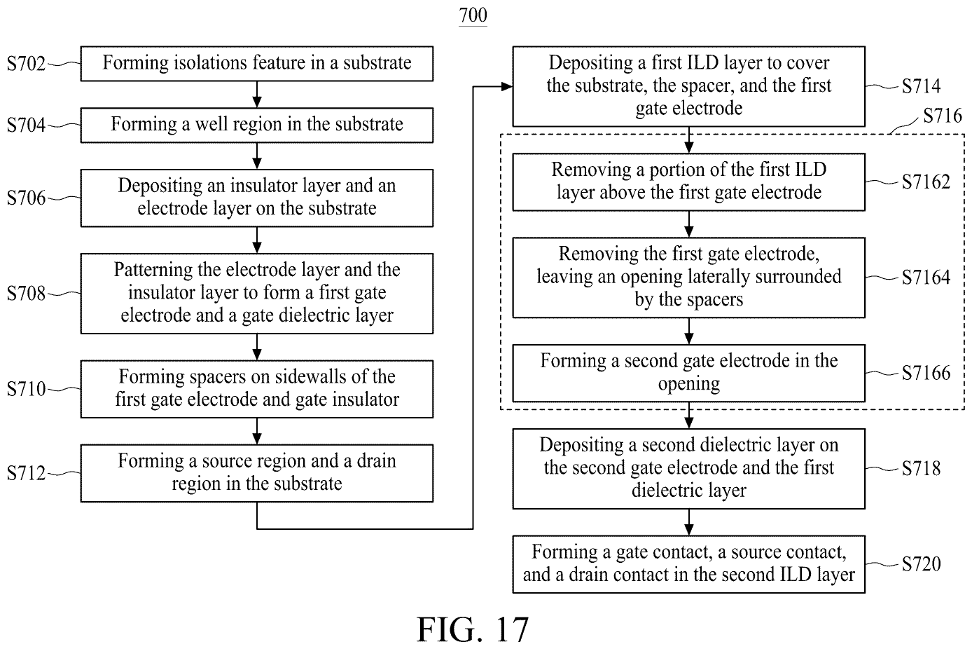

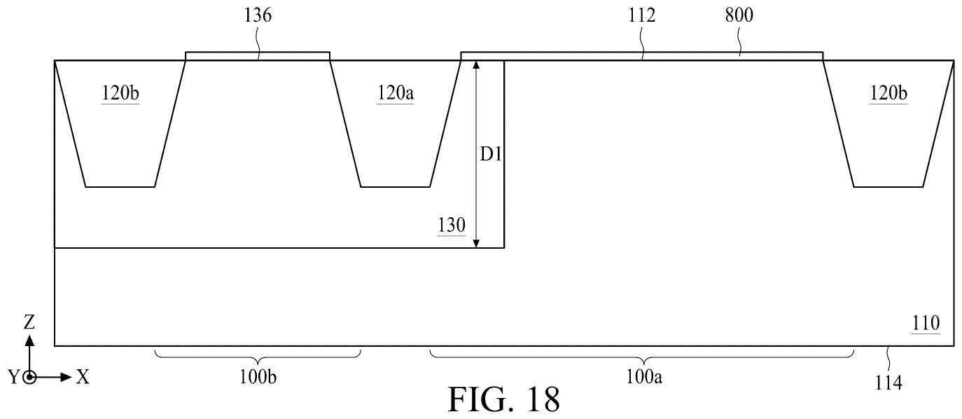

FIG. 17 is a flowchart of a method 700 of manufacturing a semiconductor device 10, in accordance with some embodiments of the present disclosure. FIGS. 18 to 25 are cross-sectional views of intermediate stages of the method 700 of manufacturing the semiconductor device 10, in accordance with some embodiments of the present disclosure. In the following description, the manufacturing stages shown in FIGS. 18 to 25 are discussed with reference to the process steps shown in FIG. 17. It should be understood that additional steps can be provided before, during, and after the steps shown in FIG. 17, and some of the steps described below can be replaced or eliminated, for additional embodiments of the method 700. The order of the steps may be changed.

Referring to FIG. 18, in some embodiments, isolation features 120a and 120b are formed in a substrate 110 in accordance with step S702 in FIG. 17. In some embodiments, the substrate 110 may be a semiconductor substrate and doped with impurities of a first conductivity type, for example p-type impurities, to form a p-type substrate. Alternatively, the substrate 110 may be doped with n-type impurities, to form an n-type substrate. In some embodiments, the substrate 110 may be doped by ion implantation processes. A doping operation may be performed in selected areas by implanting atoms into exposed regions while other areas are masked. In addition, thermal drive or anneal cycles may be used to apply thermal diffusion to expand or extend a previously doped region. In alternative embodiments, the substrate 110 may be in-situ doped during an epitaxial growth operation.

The isolation features 120a and 120b are formed in the substrate 110 to isolate a first oxide definition (OD) region 100a from a second OD region 100b. In some embodiments, the isolation features 120a and 120b may be formed using a process sequence including: forming a patterned mask layer 800 on a front surface 112 of the substrate 110, etching trenches in the substrate 112, and filling the trenches with isolation material. The trenches may be over-filled with isolation material, and a planarization operation (e.g., chemical mechanical planarization or etch back) may be subsequently performed to remove excess isolation material and thereby form the isolation features 120a and 120b in the substrate 110. After the formation of the isolation feature 120a and 120b, the patterned mask layer 800 is removed.

In some embodiments, the isolation features 120a and 120b collectively define the first OD region 100a having a polygon shape and the second OD region 100b having a rectangle shape from a top-view perspective. The first OD region 100a may include an octagonal shape as shown in FIG. 5, a rectangular shape with two rounded corners as shown in FIG. 9, a rectangle with four rounded corners or a hexagon as shown in FIG. 10. The first OD region 100a includes at least one corner area CA. In some embodiments, the corner area CA includes a rounded corner. The corner area CA may include first and second orthogonal sidewalls and a curved sidewall that connects the first and second orthogonal sidewalls to form the rounded corner. In alternative embodiments, the corner area CA includes at least a corner with an obtuse angle. The corner area CA may include first and second orthogonal sidewalls and one an inclined sidewall connecting the first and second orthogonal sidewalls. A corner included between the inclined sidewall and the first/second sidewall may have an obtuse angle. The corner area CA including the curved sidewall or the inclined sidewall may be formed in the substrate 110 by photolithography and etching operations. During the photolithography, a photomask (also referred to as a mask or a reticle) is included in a lithography system. In some embodiments, the photomask includes a pattern that contains the curved sidewall or the inclined sidewall to be transferred onto the patterned mask layer 800. The corner area CA including the curved sidewall or the inclined sidewall are not formed due to lithographic resolution issues or etching limitations. The step S702 may be also used for forming the isolation features 520 and 522 shown in FIG. 12 in the substrate 510, to thereby form the OD region 500.

Still referring to FIG. 18, a well region 130 is formed in the substrate 110 in accordance with step S704 in FIG. 17. The well region 130 may by formed by doping a portion of the substrate 110 with impurities of a second conductivity type, wherein the second conductivity type is opposite to the first conductivity type. The well region 130 extends from the front surface 112 of the substrate to a depth D1 into the substrate 110. The well region 140 may have a first surface 136 coplanar with the front surface 112 of the substrate 110.

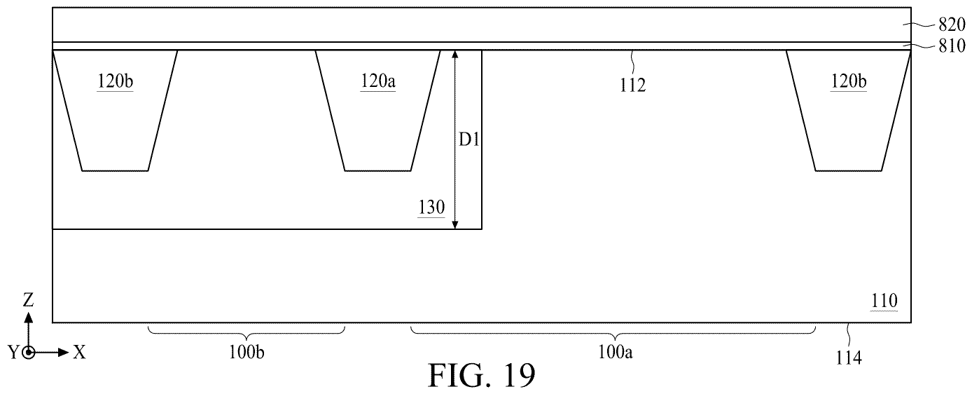

Referring to FIG. 19, a blanket insulator layer 810 and a blanket electrode layer 820 are sequentially disposed on the upper surface 112 of the substrate 110 in accordance with step 706 in FIG. 17. The insulator layer 810 may cover an entirety of the upper surface 112 of the substrate 110. The electrode layer 820 is deposited on the insulator layer 810. The insulator layer 810 may include oxide, a high-dielectric-constant (high-k) dielectric material, other dielectric materials, or a combination thereof. The insulator layer 810 may be formed by, for example, sputtering, chemical vapor deposition (CVD), physical vapor deposition (PVD), atomic layer deposition (ALD), plasma-enhanced ALD, molecular beam epitaxy (MBE), a combination thereof, or other suitable techniques. In some embodiments, the electrode layer 820 includes polysilicon, another suitable conductive material, or a combination thereof. The electrode layer 820 may be disposed by, for example, PVD, CVD, sputtering, plating, combination thereof, or other suitable techniques.

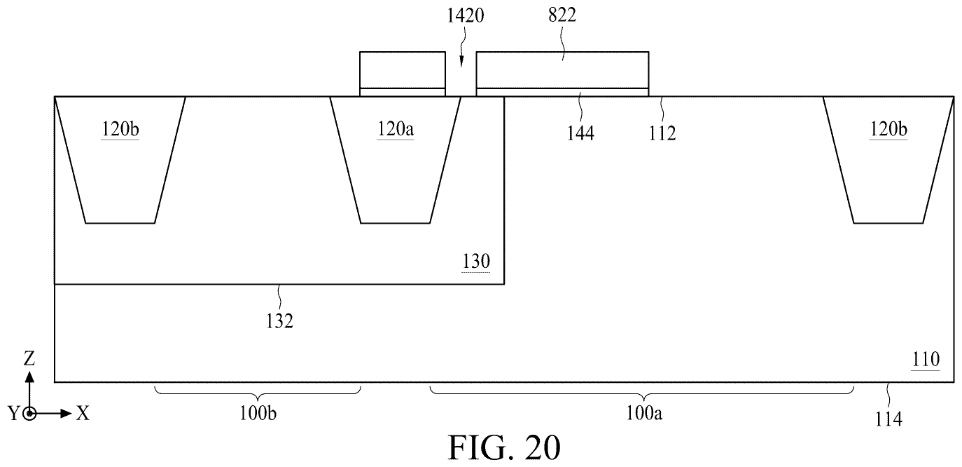

Referring to FIG. 20, the electrode layer 820 and the insulator layer 810 are patterned to form a first gate electrode 822 and a gate dielectric layer 144 in accordance with step S708 in FIG. 17. The gate dielectric layer 144 is disposed between the first OD region 100a and first gate electrode 822 and between the isolation feature 120a and the first gate electrode 822. In some embodiments, the first gate electrode 822 and the gate dielectric layer 144 include identical shapes from a top-view perspective. In embodiments where the first gate electrode 822 and the gate dielectric layer 144 have identical shapes, the electrode layer 820 and the insulator layer 810 may be patterned using a same mask pattern. In alternative embodiments, the first gate electrode 822 and the gate dielectric layer 144 include different shapes. In embodiments where the first gate electrode 822 and the gate dielectric layer 144 with different shapes from a top-view perspective, where portions of the gate dielectric layer 144 may be exposed through the first gate electrode 822, as shown in FIG. 8, and the electrode layer 820 and the insulator layer 810 are patterned using different mask patterns. The step S708 may be also used for forming the gate electrode with the configuration shown in FIGS. 14 and 16 over the OD region 500.

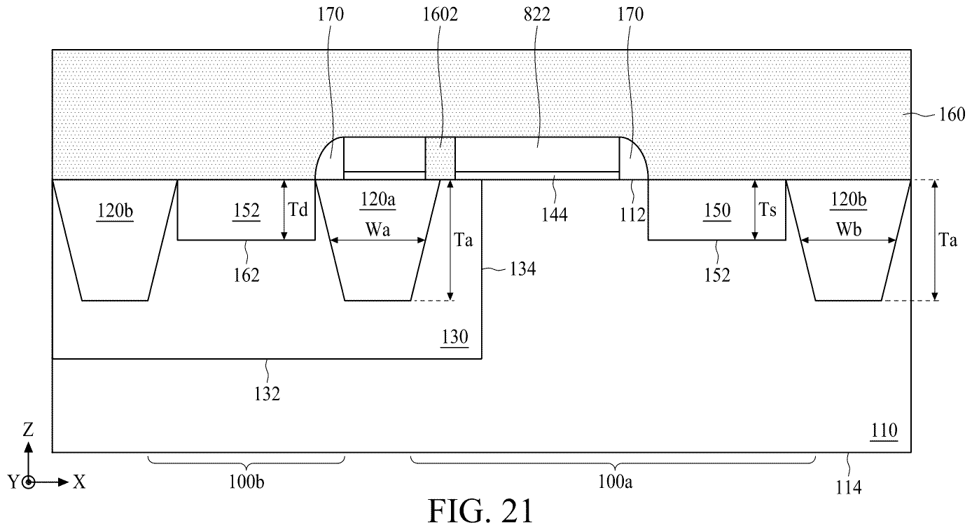

Referring to FIG. 21, spacers 170 are formed on sidewalls of the first gate electrode 822 and the gate dielectric layer 144 in accordance with step S710 in FIG. 17. The formation of the spacers 170 includes conformally depositing a spacer layer on the substrate 110, the isolation features 120a and 120b, the sidewalls of the gate dielectric layer 144 and the first gate electrode 822, and the upper surface of the first gate electrode 822, and anisotropically etching the space layer to remove horizontal portions of the spacer layer from the substrate 110 and the first gate electrode 822. The vertical portions of spacer layer on the sidewalls of the first gate electrode 822 and the gate dielectric layer 144 remain after the etching operation. The spacer layer includes a dielectric material such as silicon oxide, silicon nitride, silicon carbide, silicon oxynitride, silicon carbonitride (SiCN), silicon oxycarbonitride (SiOCN), or a combination thereof. The spacer layer may be formed using CVD, ALD, or another deposition technique. The step S710 may be also used for forming the spaces 570 shown in FIGS. 11 and 12 on sidewalls of the gate electrode 540.

Still referring to FIG. 21, a source region 150 and a drain region 152 are formed in the substrate 110 in accordance with step S712 in FIG. 17. The source region 150 may be formed by implanting ions with desired conductivity type into a portion of the first OD region 100a, which does not overlap the first gate electrode 822. The drain region 142 may be formed by implanting ions with desired conductivity type into the second OD region 100b. In some embodiments, the first gate electrode 822 and the spacer 170 provide a self-aligned mask to position the source region 150 and the drain region 152. The step S712 may be also used for forming the source and drain region shown in FIGS. 11 and 12 in the substrate 510.

After the formation of the source region 150 and the drain region 152, a first ILD layer 160 is deposited to cover the substrate 110, the spacer 170, and the first gate electrode 822 in accordance with step S714 in FIG. 17. The first ILD layer 160 laterally surrounds the spacers 170, the gate dielectric layer 144, and the first gate electrode 822. The ILD layer 160 may be in contact with the first OD region 100a, the isolation features 120a and 120b, the source region 150, and the drain region 152 exposed through the first gate electrode 822 and the gate dielectric layer 144. In embodiments where the first gate electrode 822 and the gate dielectric layer 144 include different shapes, the first ILD layer 160 is further in contact with the gate dielectric layer 144 exposed through the first gate electrode 822. In embodiments where the first gate electrode 822 is formed to have the shape shown in FIG. 9, the first ILD layer 160 may further fill the trenches of the first gate electrode 822. The first ILD layer 160 may include an oxide, a nitride, an oxynitride, a carbide, an oxycarbide, a low-k dielectric material, an ultra-low-k dielectric material, other dielectric materials, or a combination thereof. The first ILD layer 160 may be deposited by any suitable method, such as CVD, plasma enhanced CVD (PECVD), a spin-on operation, a combination thereof, or the like. The step S714 may be also used for forming the ILD layer 562 shown in FIG. 12 on the substrate 510 and laterally surrounding the spacer 570.

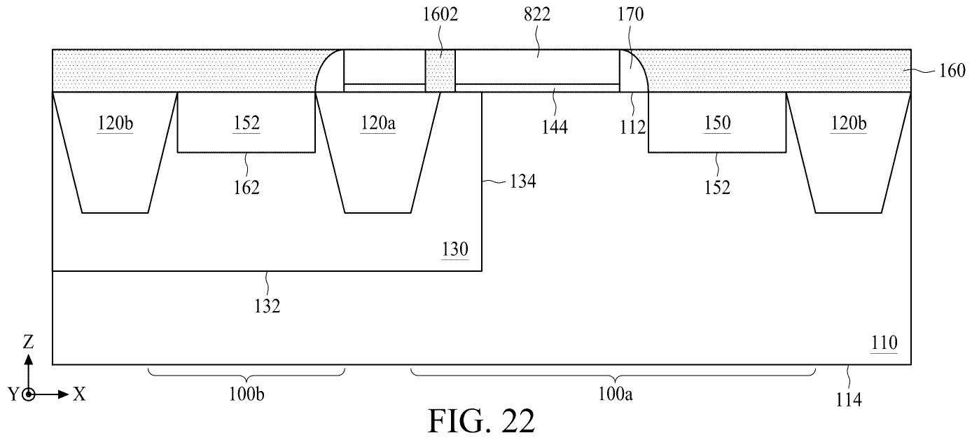

Referring to FIG. 17, the method 700 proceeds to step S716 for gate replacement. The gate replacement operation is performed, where the first gate electrode 822 of polysilicon is replaced with a metal gate electrode. Referring to FIGS. 17 and 22, a portion of the first ILD layer 160 is removed to expose the first gate electrode 822 in accordance with step S7162 in FIG. 17. In some embodiment, a planarization operation is performed to remove the portion of the first ILD layer 160 above the first gate electrode 822. The planarization operation may include, for example, a CMP operation, a grinding operation, an etching operation, the like, or combinations thereof.

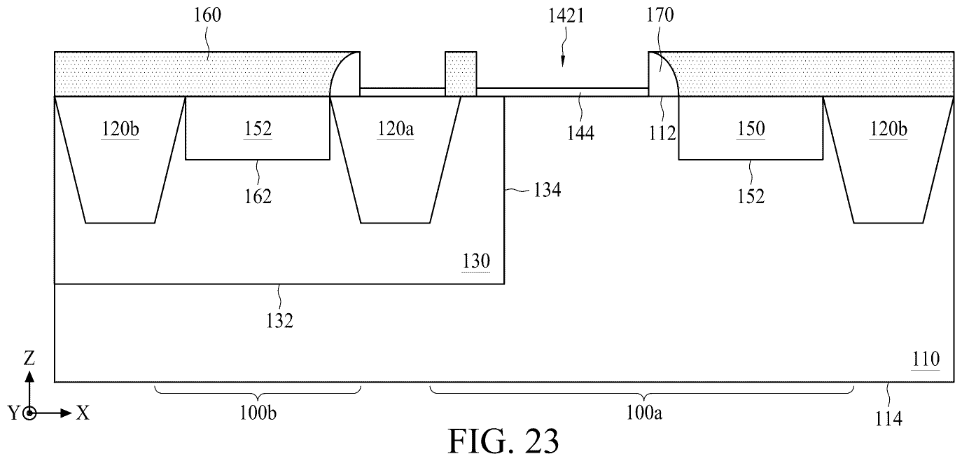

Referring to FIG. 23, the first gate electrode 822 is removed to expose the gate dielectric layer 144 in accordance with step S7164 in FIG. 17. In some embodiments, one or more etching operations are performed to remove the first gate electrode 822 laterally surrounded by the first ILD layer 160 and the spacer 170. The etching operation may be configured to have an etching selectivity between the first gate electrode 822 and the other layers, such that the first gate electrode 822 is etched away without substantially affecting the other layers. As a result, an openings 1421 is formed in both the first OD region 100a and the isolation features 120a and 120b.

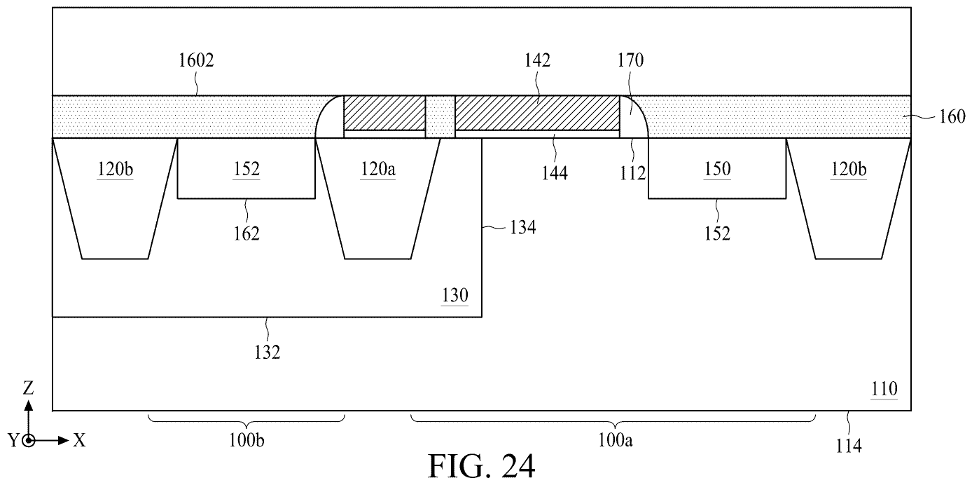

Referring to FIG. 24, a second gate electrode 142 is formed in the openings 1421 in accordance with step S7166 in FIG. 17. The second gate electrode 142 may include a work function metal layer and a conductive layer (also referred to as a fill metal). In some embodiments, the work function metal layer may include a p-type or an n-type work function material, such as TiN, TaN, or the like. In some embodiments, the conductive layer may include a metallic material or a metal compound. The second gate electrode 142 may be formed by conformally depositing the work function layer and the conductive layer on the first ILD layer 160 and in the opening 1421, and removing excess portions of the work function metal layer and the conductive material from the upper surface 1602 of the first ILD layer 160 using a CMP operation, an etch operation, or combinations thereof to form the second gate electrode 142. The step S716 may be also used for forming the gate electrode 542 shown in FIGS. 11 and 12 over the OD region 500 and the isolation features 520 and 522.

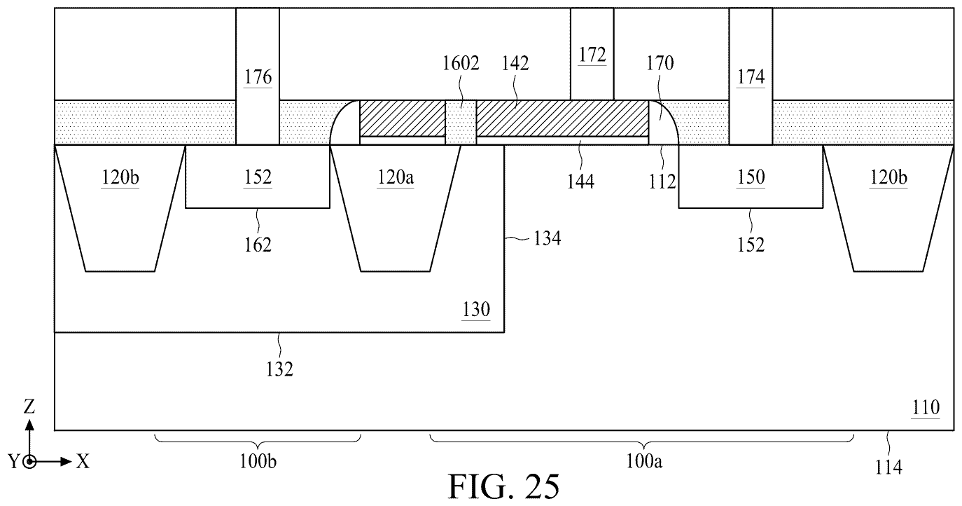

Referring to FIG. 25, a second ILD layer 162 is deposited on the second gate electrode 142 and the first ILD layer 160 in accordance with step S718 in FIG. 17. The second ILD layer 162 may be deposited by any suitable method, such as CVD, PECVD, a spin-on operation, a combination thereof, or the like. The second ILD layer 162 may include oxide, nitride, a low-k dielectric material, or the like. The second ILD layer 162 may be made of materials same as materials of the first ILD layer 160. The step S718 may be also used for forming the second ILD layer 562 shown in FIG. 12 on the gate electrode 542 and the first ILD layer 560.

Still referring to FIG. 25, a gate contact 172, a source contact 174, and a drain contact 176 are formed at least in the second ILD layer 162 in accordance with step S720 in FIG. 17. Therefore, the semiconductor device 10 shown in FIGS. 1 to 3 is completed. In some embodiments, the gate contact 172 is connected to the gate electrode 142 and laterally surrounded by the second ILD layer 162. The source contact 174 and the drain contact 176 may be connected to the source region 150 and the drain region 152, respectively, and laterally surrounded by the first and second ILD layers 160 and 162. The formation of the gate contact 142 may include performing lithography and etching operations to form a first trench in the second ILD layer 162 and expose a portion of the gate electrode 142, and to form a plurality of second trenches in the first and second ILD layers 160 and 162 to expose portions of the source region 150 and drain region 152, filling the first and second trenches with a metallic material, and performing a planarization to remove excess metallic material. The step S720 may be also used for forming the gate contact 572, the source contact 574, and the drain contact 576 shown in FIG. 11.

In accordance with some embodiments of the present disclosure, a method of fabricating a semiconductor device, includes steps of forming an isolation feature in a substrate to define a first oxide definition region and a second oxide definition region; forming an insulator layer on the isolation feature and the first oxide definition region; forming a first electrode layer on the insulator layer; patterning the first electrode layer to form a first gate electrode, wherein a corner area of the first oxide definition region is exposed through the first gate electrode; and depositing an inter-layer dielectric (ILD) layer laterally surrounding the first gate electrode and covering the corner area of the first oxide definition region and the isolation feature.

In accordance with some embodiments of the present disclosure, a method of fabricating a semiconductor device includes steps of forming an isolation feature in a substrate to define an oxide definition region; depositing an insulator layer in the substrate; depositing an electrode layer on the insulator layer; patterning the electrode layer to form a gate electrode comprising a first section and a second section connected to the first section, wherein the first section overlaps a boundary of the oxide definition region from a top-view perspective, the second section vertically overlaps the isolation feature, and the first section has a width less than a width of the second section; and depositing an inter-layer dielectric (ILD) layer laterally surrounding the gate electrode.

In accordance with some embodiments of the present disclosure, a semiconductor device includes a substrate; an isolation feature disposed in the substrate and defining an oxide definition region; a gate electrode comprising: a first section vertically overlapping the isolation feature; and a second section connected to the first section and overlapping a boundary of the oxide definition region from a top-view perspective; and a gate dielectric layer between the gate electrode and the oxide definition region and between the gate electrode and the isolation region, wherein the first section has a first width greater than a second width of the second section.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
forming an isolation feature in a substrate to define a first oxide definition region and a second oxide definition region;
forming an insulator layer on the isolation feature and the first oxide definition region;
forming a first electrode layer on the insulator layer;
patterning the first electrode layer to form a first gate electrode, wherein a corner area of the first oxide definition region is exposed through the first gate electrode; and
depositing an inter-layer dielectric (ILD) layer laterally surrounding the first gate electrode and covering the corner area of the first oxide definition region and the isolation feature.

2. The method of claim 1, further comprising, prior to the depositing of the ILD layer:
patterning the insulator layer to form a gate dielectric layer between the first gate electrode and the first oxide definition region and between the first gate electrode and the isolation feature.

3. The method of claim 2, wherein after the depositing of the ILD layer, the ILD layer is in contact with the gate dielectric layer.

4. The method of claim 2, wherein after the depositing of the ILD layer, the ILD layer is in contact with the isolation feature and the first oxide definition region.

5. The method of claim 2, further comprising:
forming spacers on sidewalls of the first gate electrode and the gate dielectric layer;
forming a source region in the first oxide definition region;
forming a drain region in the second oxide definition region prior to the forming of the depositing of the ILD layer;
removing the first gate electrode to form a trench that exposes the gate dielectric layer after the depositing of the ILD layer; and
depositing a conductive material in the trench to form a second gate electrode.

6. The method of claim 5, wherein the first gate electrode and the second gate electrode comprise:
a first section vertically overlapping the isolation feature; and
a second section connected to the first section and overlapping a boundary of the first oxide definition region from a top-view perspective.

7. The method of claim 6, wherein the first gate electrode and the second gate electrode further comprise:
a third section vertically overlapping the first oxide definition region, wherein the second section connecting the first section to the third section; and
a fourth section separated from the second section, vertically overlapping the isolation feature, and connecting the first section to the third section.

8. The method of claim 5, wherein the first gate electrode and the second gate electrode have an asymmetry H-shape from a top-view perspective.

9. The method of claim 1, wherein the corner area comprising a corner with an obtuse angle.

10. The method of claim 1, wherein the corner area comprises a rounded corner.

11. The method of claim 1, wherein the first oxide definition region comprises a curved sidewall at the corner area of the first oxide definition region.

12. The method of claim 1, wherein the first oxide definition region comprises an inclined sidewall arranged between two orthogonal sidewalls.

13. A method of manufacturing a semiconductor device, comprising:
forming an isolation feature in a substrate to define an oxide definition region;
depositing an insulator layer in the substrate;
depositing an electrode layer on the insulator layer;
patterning the electrode layer to form a gate electrode comprising a first section and a second section connected to the first section, wherein the first section overlaps a boundary of the oxide definition region from a top-view perspective, the second section vertically overlaps the isolation feature, and the first section has a width less than a width of the second section; and
depositing an inter-layer dielectric (ILD) layer laterally surrounding the gate electrode.

14. The method of claim 13, further comprising:
patterning the insulator layer to form a gate dielectric layer prior to the depositing of the ILD layer,
wherein the ILD layer is in contact with the isolation feature.

15. The method of claim 13, further comprising:
patterning the insulator layer to form a gate dielectric layer prior to the depositing of the ILD layer,
wherein a portion of the gate dielectric layer is exposed through the gate electrode.

16. The method of claim 13, wherein the oxide definition region comprises:
a middle section vertically overlapping the first section of the gate electrode; and
a first end section and a second end section on two sides of the middle section and are non-overlapped with the gate electrode.

17. A semiconductor device, comprising:
a substrate;
an isolation feature disposed in the substrate and defining an oxide definition region;
a gate electrode comprising:
a first section vertically overlapping the isolation feature; and
a second section connected to the first section and overlapping a boundary of the oxide definition region from a top-view perspective; and
a gate dielectric layer between the gate electrode and the oxide definition region and between the gate electrode and the isolation feature,
wherein the first section has a first width greater than a second width of the second section.

18. The semiconductor device of claim 17, wherein a portion of the gate dielectric layer is exposed through the gate electrode.

19. The semiconductor device of claim 17, wherein the oxide definition region comprises a corner area exposed through the gate electrode.

20. The semiconductor device of claim 19, wherein the oxide definition region comprises a corner with an obtuse angle.
